(19) United States
(12) Patent Application Publication
(10) Pub. No.: US 2026/0366904 A1
(43) Pub. Date: Nov. 19, 2026

(54) DEVICE FOR MEASURING WEIGHT OF SUBSTRATE, APPARATUS FOR DRYING SUBSTRATE INCLUDING THE SAME AND METHOD FOR MEASURING WEIGHT OF SUBSTRATE

(71) Applicant: KCTECH CO., LTD., Gyeonggi-do (KR)

(72) Inventors: Dong Hwa LEE, Gyeonggi-do (KR); Yun Seok LEE, Gyeonggi-do (KR); Seung Kyo KIM, Gyeonggi-do (KR)

(21) Appl. No.: 19/675,903

(22) Filed: May 13, 2026

(30) Foreign Application Priority Data
May 14, 2025 (KR) 10-2025-0062771

(51) Int. Cl. G01G 19/00; H10P 72/00

(52) U.S. Cl. CPC G01G 19/00; H10P 72/0408

(57) ABSTRACT

Disclosed is a device for measuring weight of a substrate comprising a measurement placing portion provided under a substrate and configured to support a central region of the substrate; a load cell provided under the measurement placing portion and being in contact with the measurement placing portion; and a fixing member provided under the load cell and configured to fix the load cell.

### CROSS-REFERENCE TO RELATED APPLICATIONS

This application claims the benefit of the Korean Patent Application No. 10-2025-0062771 filed on May 14, 2025 which is hereby incorporated by reference as if fully set forth herein.

### FIELD

The present disclosure relates to a device for measuring weight of a substrate, an apparatus for drying a substrate including the same, and a method for measuring weight of a substrate, and more particularly, to a device for measuring weight of a substrate, which is capable of accurately measuring weight of an anti-drying solution coated onto a substrate when a supercritical fluid is coated and a drying process for a substrate is performed, an apparatus for drying a substrate including the same, and a method for measuring weight of a substrate.

### BACKGROUND

A semiconductor is produced through a processing process such as a deposition process of depositing a thin film of a specific material on a substrate, a photo process of selectively exposing the thin film using a photosensitive material, and an etching process of forming a pattern by removing the thin film of the selectively exposed portion. In this case, impurities such as metal, particles, and organic matters generated during the processing process have an important effect on yield and quality of the semiconductor. To this end, a cleaning process and a drying process of removing the impurities from the substrate are required.

Meanwhile, a supercritical substrate processing apparatus performs a drying process on a substrate which completes a cleaning process. The drying process is performed to remove liquid remaining on the substrate after the cleaning process. The drying process may be performed in a high-temperature and high-pressure chamber.

It is preferable to coat a predetermined amount of an anti-drying solution for the drying process to the substrate, and it is necessary to accurately measure weight of the anti-drying solution coated to the substrate.

FIGS. 1 and 2 show a device for measuring weight of an anti-drying solution applied on a substrate according to the related art.

Referring to FIGS. 1 and 2, a substrate (w) is positioned inside a particle cover 100 for protecting a substrate from external particles or the like, and both edge regions of the substrate are supported by a contact member 210 on a body 200. In addition, each body 200 is connected to a measurement placing portion 300, and the measurement placing portion 300 may be extended to an upper side without being in contact with the particle cover 100 after being withdrawn to the outside of the particle cover 100.

A load cell 500 is provided on an upper portion of the particle cover 100, and a load of the measurement placing portion 300 is transmitted to the load cell 500 through a fixing member 400 provided on the load cell 500, to thereby measure weight of the substrate (w).

In the structure according to FIGS. 1 and 2, the load cell 500 is provided while being in contact with the upper portion of the particle cover 100, and the fixing member 400 is provided while being in contact with the measurement placing portion 300 and being spaced apart from the load cell 500. When the substrate (w) is placed on the contact member 210 on the body 200, the load of the substrate (w) is transmitted to the body 200 and the measurement placing portion 300 through the contact member 210 and then transmitted to the load cell 500 through the fixing member 400.

In this case, since the measurement placing portion 300 is in a floating state without being fixed to the load cell 500, it may be shaken by the flow of air or the like, whereby the weight measurement may not be accurate. In addition, only two edge regions of the substrate (w) are supported by the contact member 210 on the body 200, the substrate (w) may be disposed on the contact member 210 on the body 200 while being spaced apart from the accurate position of the substrate (w), whereby the load of the substrate (w) may not be properly transmitted to the load cell 500.

The present disclosure has been made in view of the above problems, and it is an object of the present disclosure to accurately measure weight of an anti-drying solution coated on a substrate for a drying process.

In accordance with an aspect of the present disclosure, the above and other objects can be accomplished by the provision of a device for measuring weight of a substrate comprising a measurement placing portion provided under a substrate and configured to support a central region of the substrate; a load cell provided under the measurement placing portion and being in contact with the measurement placing portion; and a fixing member provided under the load cell and configured to fix the load cell.

The measurement placing portion may include a first body, at least three support arms branched from the first body, and a contact member provided on an upper portion of each of the support arms and configured to be in contact with the substrate.

The load cell may be formed in a cantilever shape on an upper surface of the fixing member.

The fixing member may include a first fixing member provided in a direction crossing an arrangement direction of the load cell; a second fixing member vertically arranged under the first fixing member; a base plate provided below the second fixing member; and an intermediate plate for fixing the second fixing member to the base plate.

The load cell may have a first length in a first direction and a second length in a second direction crossing the first direction, and the first length may be greater than the second length.

The first fixing member may have a third length in the first direction and a fourth length in the second direction, and the fourth length may be greater than the third length.

The second fixing member may have an upper first portion and a lower second portion, the first portion may have a fifth length in the first direction and a sixth length in the second direction, the sixth length may be greater than the fifth length, the second portion may have a seventh length in the first direction and an eighth length in the second direction, and the eighth length may be greater than the seventh length.

The fifth length may be greater than the seventh length.

The eighth length may be greater than the sixth length.

A height of the first portion may be greater than a height of the second portion.

The intermediate plate may include a third portion provided in the second direction and a fourth portion extending in the first direction from both ends of the third portion.

The third portion may have a ninth length in the first direction, and the fourth portion has a tenth length in the first direction, and the tenth length may be greater than the ninth length.

In accordance with another aspect of the present disclosure, the above and other objects can be accomplished by the provision of an apparatus for drying a substrate comprising a chamber for processing a substrate; a particle cover provided in an entrance direction of the chamber; and a device for measuring weight of a substrate described above and provided inside the particle cover.

The apparatus may further comprise a transporting robot for loading the substrate into the chamber and unloading the substrate from the chamber, wherein the load cell may be provided in a cantilever shape on an upper surface of the fixing member, and the transporting robot may transport the substrate in a long axis direction of the cantilever shape.

In accordance with another aspect of the present disclosure, the above and other objects can be accomplished by the provision of a method for measuring weight of a substrate comprising a step of transporting a substrate coated with an anti-drying solution into the inside of a particle cover provided in an entrance direction of a chamber; a step of measuring weight of the substrate inside the particle cover; a step of loading the substrate into the inside of the chamber and drying the substrate; a step of unloading the substrate to the outside of the chamber and measuring the weight of the substrate; and a step of measuring weight of the anti-drying solution from a difference value between the weight before the drying process and the weight after the drying process.

The step of measuring the weight of the substrate may include supporting a central region of the substrate on a measurement placing portion provided under the substrate; and bringing a load cell into contact with a lower surface of the measurement placing portion.

The load cell may be fixed to a lower fixing member, and the load cell may be provided in a cantilever shape on an upper surface of the fixing member.

The measurement placing portion may include a first body, at least three support arms branched from the first body, and a contact member provided on an upper portion of each of the support arms, wherein the contact member may be in contact with the substrate.

The fixing member may be provided to include a first fixing member, a second fixing member, and a base plate provided in a direction crossing an arrangement direction of the load cell.

At least one of the first fixing member, the second fixing member, and the base plate may be disposed in the direction crossing the arrangement direction of the load cell while being provided longer than the arrangement direction of the load cell.

It is to be understood that both the foregoing general description and the following detailed description of the present disclosure are exemplary and explanatory and are intended to provide further explanation of the disclosure as claimed.

### BRIEF DESCRIPTION OF THE DRAWINGS

The above and other objects, features and other advantages of the present disclosure will be more clearly understood from the following detailed description taken in conjunction with the accompanying drawings. In the drawings:

FIG. 1 is a perspective view of a device for measuring weight of an anti-drying solution applied on a substrate according to the related art;

FIG. 2 is a side view of the device for measuring weight of an anti-drying solution coated on the substrate of FIG. 1;

FIG. 3 is a view showing a device for measuring weight of a substrate according to an embodiment of the present disclosure;

FIG. 4 is a view showing a measurement placing portion of FIG. 3.

FIG. 5 is a view showing a load cell of FIG. 3;

FIG. 6 is a view showing a first fixing member of FIG. 3;

FIG. 7 is a view showing a second fixing member of FIG. 3;

FIG. 8 is a view showing an intermediate plate of FIG. 3;

FIGS. 9 and 10 are views showing a weight measurement of a substrate inside a particle cover adjacent to a drying chamber; and

FIG. 11 shows a method for measuring weight of a substrate according to an embodiment of the present disclosure.

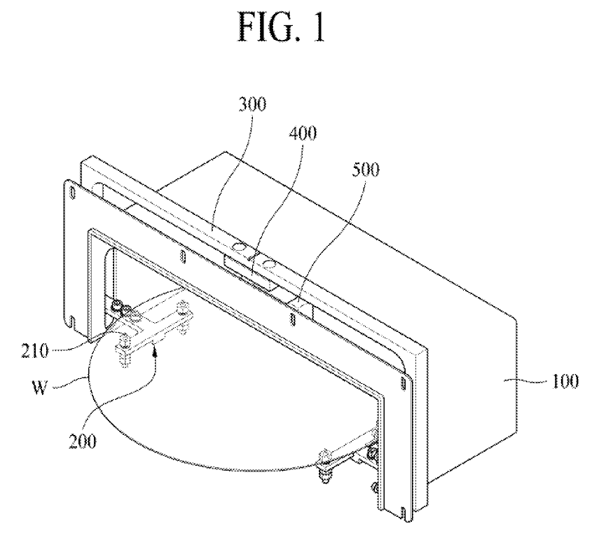

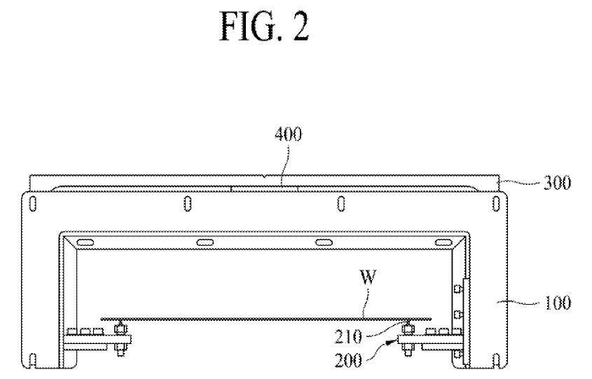

### DETAILED DESCRIPTION

Hereinafter, some embodiments of the present disclosure will be described in detail with reference to exemplary drawings. It should be noted that, when reference numerals are added to components of each drawing, the same components have the same reference numeral even if displayed on different drawings. In addition, in describing the embodiment of the present disclosure, when it is determined that a detailed description of a related configuration or function interferes with the understanding of the embodiment of the present disclosure, the detailed description thereof will be omitted.

In the description of the embodiment according to the present disclosure, in the case of being described as being formed “on (above) or under (below)” of each element, it includes all that two elements are in direct contact with each other or are indirectly provided with other elements interposed therebetween. Also, if expressed as “on or under”, the meaning of the downward direction as well as the upward direction with respect to one element may be included.

In a device for measuring weight of a substrate according to the present disclosure, an apparatus for drying a substrate including the same, and a method for measuring weight of a substrate, weight of the substrate is measured in a state in which an anti-drying solution is removed after a drying process, and weight of the anti-drying solution may be obtained from a difference value between measured weights. Also, when measuring the weight of the substrate, a load cell is in contact with a lower portion of the substrate so that it is possible to prevent an error in weight measurement due to a flow of air or the like.

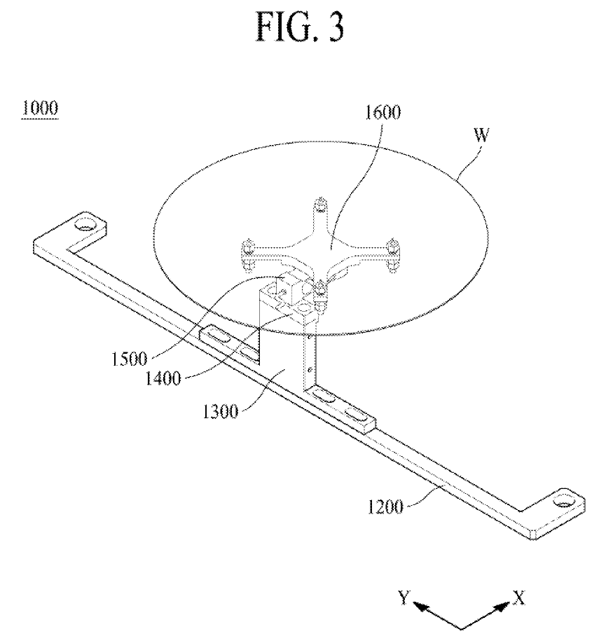

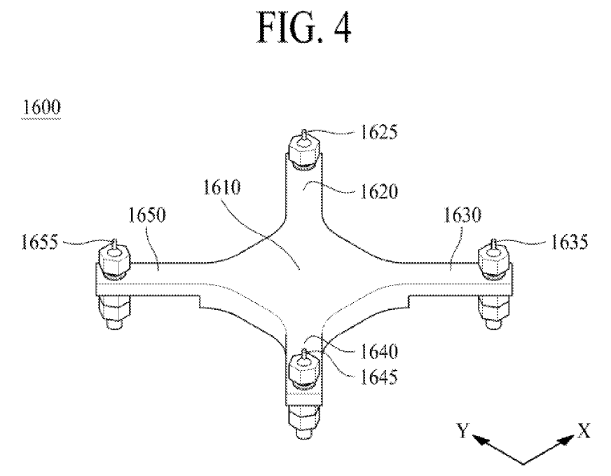

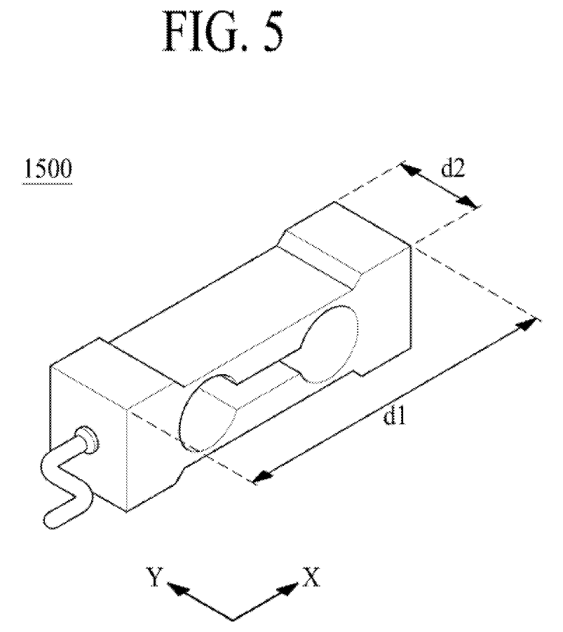

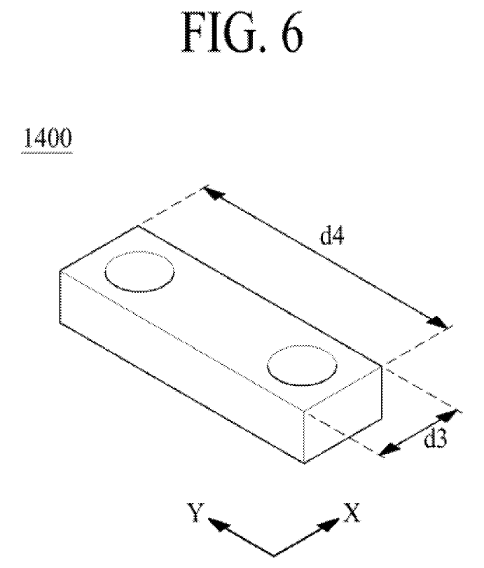

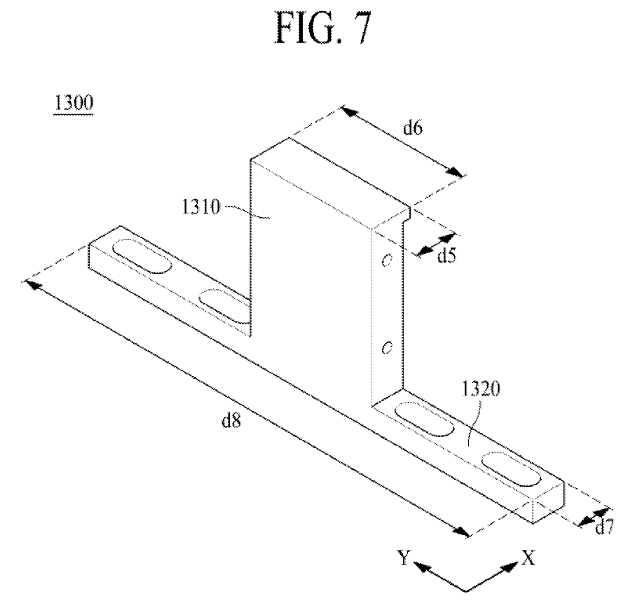

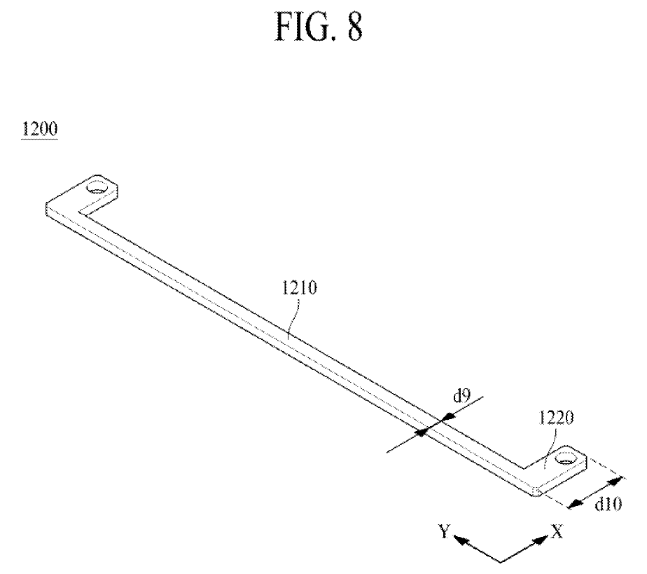

FIG. 3 is a view showing a device for measuring weight of a substrate according to an embodiment of the present disclosure. FIG. 4 is a view showing a measurement placing portion of FIG. 3. FIG. 5 is a view showing a load cell of FIG. 3. FIG. 6 is a view showing a first fixing member of FIG. 3. FIG. 7 is a view showing a second fixing member of FIG. 3. FIG. 8 is a view showing an intermediate plate of FIG. 3.

Referring to FIG. 3, a device 1000 for measuring weight of a substrate according to an embodiment of the present disclosure may include a measurement placing portion 1600 for supporting the center of a lower surface of a substrate (w), a load cell 1500 provided below the measurement placing portion 1600 and being in direct contact with the measurement placing portion 1600, and a fixing member provided below the load cell 1500 and configured to fix the load cell 1500.

The fixing member may include a first fixing member 1400 provided in a direction crossing an arrangement direction of the load cell 1500, a second fixing member 1300 disposed in a vertical direction under the first fixing member 1400, a base plate 1100 provided below the second fixing member 1300, and an intermediate plate 1200 for fixing the second fixing member 1300 to the base plate 1100.

Herein, the arrangement direction of the load cell 1500 indicates a length direction of the load cell 1500 and may be an X-axis direction in FIG. 5 to be described later.

In FIG. 3, the X-axis and the Y-axis are shown, and the X-axis and the Y-axis shown in FIGS. 4-8 are the same as the X-axis and the Y-axis shown in FIG. 3.

Referring to FIG. 4, the measurement placing portion 1600 may include a first body 1610 provided in a central region and at least three support arms branched from the first body 1610. In this embodiment of the present disclosure, the four support arms 1620, 1630, 1640 and 1650 may be provided, and contact members 1625, 1635, 1645 and 1655 may be respectively provided above the support arms 1620, 1630, 1640 and 1650.

The body 1610 may be provided in parallel with the substrate (w) disposed thereabove, and each of the support arms 1620, 1630, 1640 and 1650 may have the same angle. In this embodiment of the present disclosure, each of the support arms 1620, 1630, 1640 and 1650 may have 90 degrees (°). The contact members 1625, 1635, 1645 and 1655 may have elasticity or may be formed of a resin-based material such that the substrate (w) being in direct contact therewith is not damaged.

The substrate (w) disposed on the measurement placing portion 1600 may be a substrate used for manufacturing a semiconductor such as a silicon substrate, a silicon carbide substrate or a sapphire substrate.

Referring to FIGS. 3 and 5, the load cell 1500 may be provided under the measurement placing portion 1600 and may be provided on the fixing member, particularly, the first fixing member 1400. The load cell 1500 may be provided in a cantilever shape on the first fixing member 1400.

The load cell 1500 is a device for sensing a load such as weight, pressure, or force and converting the load into an electrical signal. The cantilever shape indicates a shape whose one end is fixedly provided and the other end is freely provided. The cantilever shape supports the load through bending moment and shear force generated in its fixed end.

The configuration and cantilever shape of the load cell 1500 are generally known to those in the art, whereby a detailed description thereof is omitted.

In FIG. 5, the load cell 1500 has a first length (d1) in the X-axis direction, that is, the first direction, and has a second length (d2) in the Y-axis direction, that is, the second direction, wherein the first length (d1) is greater than the second length (d2) and the load cell 1500 may be provided in the cantilever shape.

The first fixing member 1400 is provided under the load cell 1500 while being in direct contact with the load cell 1500. Referring to FIG. 6, the first fixing member 1400 has a third length (d3) in the X-axis direction, that is, the first direction, and has a fourth length (d4) in the Y-axis direction, that is, the second direction, wherein the fourth length (d4) may be greater than the third length (d3).

Referring to FIG. 7, the second fixing member 1300 may include an upper first portion 1310 and a lower second portion 1320, the second fixing member 1300 may be positioned vertically below the first fixing member 1400, and a height of the first portion 1310 may be higher than a height of the second portion 1320.

The first portion 1310 has a fifth length (d5) in the X-axis direction, that is, the first direction, and has a sixth length (d6) in the Y-axis direction, that is, the second direction, wherein the sixth length (d6) may be greater than the fifth length (d5).

In addition, the second portion 1320 has a seventh length (d7) in the X-axis direction, that is, the first direction and has an eighth length (d8) in the Y-axis direction, that is, the second direction, wherein the eighth length (d8) may be greater than the seventh length (d7). Also, the Y-axis direction of the second portion 1320, that is, the eighth length (d8) of the second direction is greater than the Y-axis direction of the first portion 1310, that is, the sixth length (d6) of the second direction, whereby the second fixing member 1300 may be stably provided as a whole.

In addition, the X-axis direction of the first portion 1310, that is, the fifth length (d5) of the first direction may be greater than the X-axis direction of the second portion 1320, that is, the seventh length (d7) of the first direction. This is because the first portion 1310 of the second fixing member 1300 has a shape in which the cross-sectional area of the upper surface is larger than the cross-sectional area of the lower surface. In the first portion 1310 of the second fixing member 1300, the cross-sectional area of the upper surface is larger than the cross-sectional area of the lower surface, whereby the first fixing member 1400 may be stably supported.

Referring to FIG. 8, the intermediate plate 1200 may include a third portion 1210 provided in the Y-axis direction, that is, the second direction, and a fourth portion 1220 provided in the X-axis direction, that is, the first direction, at both ends of the third portion 1210. In addition, the third portion 1210 may have a ninth length (d9) in the X-axis direction, that is, the first direction, and the fourth portion 1220 may have a tenth length (d10) in the X-axis direction, that is, the first direction.

In addition, the tenth length (d10) may be greater than the ninth length (d9). In the intermediate plate 1200 of FIG. 8, the fourth portion 1220 extends in the X-axis direction from both ends of the third portion 1210, but the fourth portion 1220 may extend in a direction opposite to that shown, that is, the -X-axis direction.

The intermediate plate 1200 is disposed on the lower base plate 1100, whereby it is possible to form the device 1000 for measuring weight of a substrate from the lowest base plate 1100 to the uppermost measurement placing portion 1600.

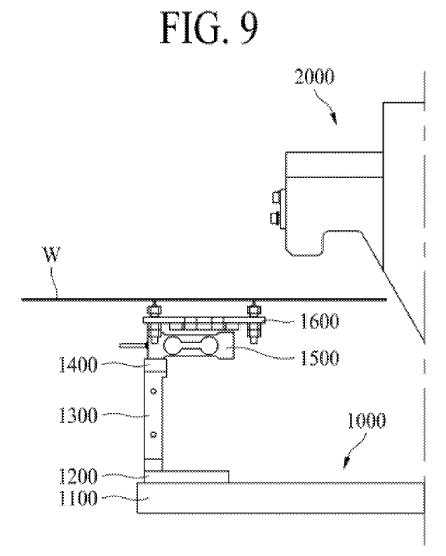

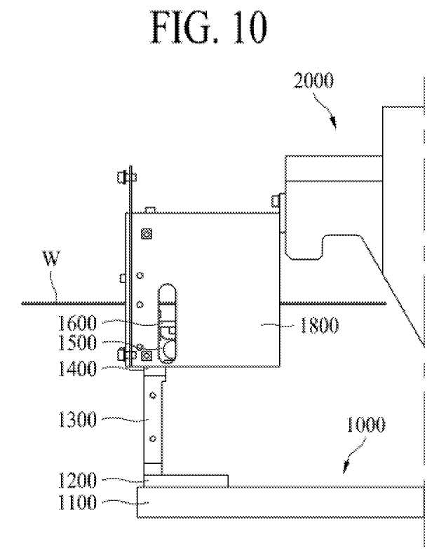

FIGS. 9 and 10 are views showing the weight measurement of the substrate inside the particle cover adjacent to a drying chamber. Hereinafter, an apparatus for drying a substrate according to an embodiment of the present disclosure will be described with reference to FIGS. 9 and 10.

FIG. 9 shows that the substrate (w) is disposed on the measurement placing portion 1600 in the device 1000 for measuring weight of a substrate and approaches a chamber 2000, and FIG. 10 shows a state in which the device 1000 for measuring weight of a substrate is disposed inside the particle cover 1800 in FIG. 9.

The chamber 2000 provides a space in which the processing process of the substrate is performed. Particularly, a drying process of the substrate may be performed in the chamber 2000. The particle cover 1800 is provided in an entrance direction of the chamber 2000 and provides a space for measuring the weight of the substrate (w) in the device 1000 for measuring weight of a substrate. The particle cover 1800 protects the substrate (w) from surrounding particles when measuring the weight of the substrate (w), and the shape of the particle cover 1800 is not limited to the illustrated configuration.

The device 1000 for measuring weight of a substrate and the particle cover 1800 are provided in the entrance direction of the chamber 2000, and a transporting robot (not shown) for loading the substrate (w) disposes the substrate (w) on the measurement placing portion 1600 of the device 1000 for measuring weight of a substrate. After measuring the weight of the substrate (w) in the load cell 1500, the transporting robot may load the substrate (w) to the inside of the chamber 2000 again.

In this case, a direction in which the transporting robot transports the substrate (w) may be a horizontal axis direction in FIGS. 9 and 10. In FIGS. 3-8, it may be the X-axis direction, that is, a long axis direction of the cantilever shape of the load cell.

After the drying process of the substrate is completed in the chamber 2000, the anti-drying solution on the substrate (w) is removed, and then an unloading process of the substrate (w) may be performed in a direction opposite to the loading direction of the substrate (w). That is, the transporting robot disposes the substrate (w) on the measurement placing portion 1600 of the device 1000 for measuring weight of a substrate from the chamber 2000. After measuring the weight of the substrate (w) in the load cell 1500, the transporting robot may unload the substrate (w) to the outside of the apparatus for drying a substrate.

In this case, a direction in which the transporting robot transports the substrate (w) may be a horizontal axis direction in FIGS. 9 and 10. In FIGS. 3-8, it may be the -X axis direction.

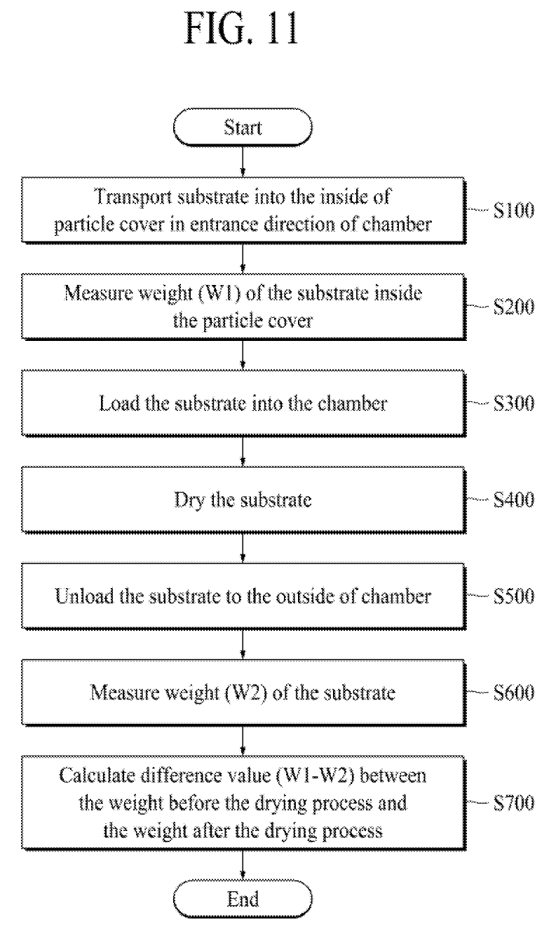

FIG. 11 shows a method for measuring weight of a substrate according to an embodiment of the present disclosure. Hereinafter, a method for measuring weight of a substrate according to an embodiment of the present disclosure will be described with reference to FIG. 11.

The method for measuring weight of a substrate according to the present embodiment is a method for measuring the weight of the substrate by using the above-described device for measuring weight of a substrate and the above-described apparatus for drying a substrate.

First, the transporting robot transports the substrate to the inside of the particle cover in the entrance direction of the chamber (S100). In this case, the substrate may be in a state in which the anti-drying solution is coated after the cleaning process.

In addition, the weight of the substrate may be measured inside the particle cover (S200). The weight of the substrate may be measured using the device for measuring weight of a substrate shown in FIGS. 3-8. That is, the central region of the substrate is supported by the measurement placing portion provided therebelow and the load cell is in contact with the lower surface of the measurement placing portion, to thereby measure the weight of the substrate.

Specifically, as shown in FIG. 4, the measurement placing portion may include the first body, at least three support arms branched from the first body, the contact member provided on each of the support arms, and the contact member may be in direct contact with the substrate.

In this case, the load cell is provided in the cantilever shape on the upper surface of the lower fixing member and is configured to measure the weight of the substrate.

Also, the fixing member may include the first fixing member, the second fixing member, and the base plate provided in the direction crossing the arrangement direction of the load cell. In addition, for the stable arrangement of the device for measuring weight of a substrate and the accuracy of the weight measurement of the substrate, at least one of the first fixing member, the second fixing member, and the base plate may be disposed in the direction crossing the arrangement direction of the load cell while being provided longer than the arrangement direction of the load cell.

In the process of step S200, the measured weight of the substrate may be referred to as ‘W1’.

In addition, the transporting robot may load the substrate into the inside of the chamber (S300) and may dry the substrate inside the chamber (S400).

The anti-drying solution, which is an organic solvent coated during the cleaning process, remains on the substrate loaded into the chamber after the cleaning process. For the drying process, a fluid of a supercritical state is sprayed to the anti-drying solution in the high-temperature and high-pressure chamber, so that it is possible to replace and remove the anti-drying solution coated onto the substrate.

Then, the transporting robot may unload the substrate from which the anti-drying solution is removed to the outside of the chamber (S500) and may measure the weight of the substrate inside the particle cover (S600). The weight of the substrate may be measured using the device for measuring weight of a substrate shown in FIGS. 3-8. In this case, the measured weight of the substrate may be referred to as ‘W2’.

In addition, a difference value between the weight (W1) of the substrate before the drying process and the weight (W2) of the substrate after the drying process is calculated, and the difference value (W1-W2) may be the same as the weight of the anti-drying solution removed in the above-described process.

According to the device for measuring weight of a substrate according to the present disclosure, the apparatus for drying a substrate including the same, and the method for measuring weight of a substrate, the weight of the substrate coated with the anti-drying solution is measured before and after the drying process, and the coating weight of the anti-drying solution may be accurately measured from the weight difference.

In addition, when measuring the weight of the substrate, the measurement placing portion and the load cell are in direct contact with each other below the central region of the substrate, and the load transmitted from the upper portion is measured, so that the load of the substrate is directly transmitted to the load cell without shaking the substrate due to the flow of air, thereby accurately measuring the weight of the substrate.

According to the device for measuring weight of a substrate according to an embodiment of the present disclosure, the apparatus for drying a substrate including the same, and the method for measuring weight of a substrate, the weight of the substrate coated with the anti-drying solution is measured before and after the drying process, the coating weight of the anti-drying solution may be accurately measured from the weight difference.

Also, when measuring the weight of the substrate, the measurement placing portion and the load cell are in direct contact with the lower surface of the central region of the substrate, and the load transmitted from its upper side is measured, so that the load of the substrate is directly transmitted to the load cell without shaking the substrate by the flow of air, thereby accurately measuring the weight of the substrate.

The above description is merely illustrative of the technical idea of the present invention, and various modifications and variations may be made by a person skilled in the art to which the present invention belongs without departing from the essential characteristics of the present invention. Therefore, the embodiments disclosed in the present invention are not intended to limit the technical idea of the present invention but to explain the technical idea of the present invention, and the scope of the technical idea of the present invention is not limited by these embodiments. The scope of the present disclosure should be construed on the basis of the claims, and all technical ideas within the scope equivalent to the claims should be construed as being included in the scope of the present disclosure.

What is claimed is:

1. A device for measuring weight of a substrate comprising:
a measurement placing portion provided under a substrate and configured to support a central region of the substrate;
a load cell provided under the measurement placing portion and being in contact with the measurement placing portion; and
a fixing member provided under the load cell and configured to fix the load cell.

2. The device of claim 1, wherein the measurement placing portion includes:
a first body, at least three support arms branched from the first body, and a contact member provided on an upper portion of each of the support arms and configured to be in contact with the substrate.

3. The device of claim 1, wherein the load cell is formed in a cantilever shape on an upper surface of the fixing member.

4. The device of claim 1, wherein the fixing member includes:
a first fixing member provided in a direction crossing an arrangement direction of the load cell;
a second fixing member vertically arranged under the first fixing member;
a base plate provided below the second fixing member; and
an intermediate plate for fixing the second fixing member to the base plate.

5. The device of claim 4, wherein the load cell has a first length in a first direction and a second length in a second direction crossing the first direction, and
the first length is greater than the second length.

6. The device of claim 5, wherein the first fixing member has a third length in the first direction and a fourth length in the second direction, and
the fourth length is greater than the third length.

7. The device of claim 6, wherein the second fixing member has an upper first portion and a lower second portion,
the first portion has a fifth length in the first direction and a sixth length in the second direction, and the sixth length is greater than the fifth length, and
the second portion has a seventh length in the first direction and an eighth length in the second direction, and the eighth length is greater than the seventh length.

8. The device of claim 7, wherein the fifth length is greater than the seventh length.

9. The device of claim 7, wherein the eighth length is greater than the sixth length.

10. The device of claim 7, wherein a height of the first portion is greater than a height of the second portion.

11. The device of claim 7, wherein the intermediate plate includes a third portion provided in the second direction and a fourth portion extending in the first direction from both ends of the third portion.

12. The device of claim 11, wherein the third portion has a ninth length in the first direction, and the fourth portion has a tenth length in the first direction, and
the tenth length is greater than the ninth length.

13. An apparatus for drying a substrate comprising:
a chamber for processing a substrate;
a particle cover provided in an entrance direction of the chamber; and
a device for measuring weight of a substrate provided inside the particle cover,
wherein the device for measuring weight of a substrate comprises a measurement placing portion provided under a substrate and configured to support a central region of the substrate, a load cell provided under the measurement placing portion and being in contact with the measurement placing portion, and a fixing member provided under the load cell and configured to fix the load cell.

14. The apparatus of claim 13, further comprising:
a transporting robot for loading the substrate into the chamber and unloading the substrate from the chamber,
wherein the load cell is provided in a cantilever shape on an upper surface of the fixing member, and
the transporting robot transports the substrate in a long axis direction of the cantilever shape.

15. A method for measuring weight of a substrate comprising:
a step of transporting a substrate coated with an anti-drying solution into the inside of a particle cover provided in an entrance direction of a chamber;
a step of measuring weight of the substrate inside the particle cover;
a step of loading the substrate into the inside of the chamber and drying the substrate;
a step of unloading the substrate to the outside of the chamber and measuring the weight of the substrate; and
a step of measuring weight of the anti-drying solution from a difference value between the weight before the drying process and the weight after the drying process.

16. The method of claim 15, wherein the step of measuring the weight of the substrate includes:
supporting a central region of the substrate on a measurement placing portion provided under the substrate; and
bringing a load cell into contact with a lower surface of the measurement placing portion.

17. The method of claim 16, wherein the load cell is fixed to a fixing member provided below the load cell, and the load cell is provided in a cantilever shape on an upper surface of the fixing member.

18. The method of claim 16, wherein the measurement placing portion includes:
a first body, at least three support arms branched from the first body, and a contact member provided on an upper portion of each of the support arms,
wherein the contact member is in contact with the substrate.

19. The method of claim 18, wherein the fixing member is provided to include a first fixing member, a second fixing member, and a base plate provided in a direction crossing an arrangement direction of the load cell.

20. The method of claim 19, wherein at least one of the first fixing member, the second fixing member, and the base plate is disposed in the direction crossing the arrangement direction of the load cell while being provided longer than the arrangement direction of the load cell.
